(19) United States
(12) Patent Application Publication
(10) Pub. No.: US 2017/0244365 A1
(43) Pub. Date: Aug. 24, 2017

(54) SINGLE-INPUT SINGLE-OUTPUT TWO-BOX POLAR BEHAVIORAL MODEL FOR ENVELOPE TRACKING POWER AMPLIFIERS

(71) Applicant: KING FAHD UNIVERSITY OF PETROLEUM AND MINERALS, DHAHRAN (SA)

(72) Inventors: OUALID HAMMI, SHARJAH (AE); SAIF NAJMEDDINE, DHAHRAN (SA)

(21) Appl. No.: 15/050,424

(22) Filed: Feb. 22, 2016

(51) Int. Cl. H03F 1/02; H03F 3/21; G01R 21/133; H03F 3/19

(52) U.S. Cl. CPC H03F 1/0222; H03F 3/19; H03F 3/21; G01R 21/133; H03F 2200/102; H03F 2200/451

(57) ABSTRACT

The single-input single-output two-box polar behavioral model for envelope tracking power amplifiers estimates magnitude and phase of the output signal in separate paths. More specifically, the model is a two-box polar behavioral model using a complex magnitude and phase splitter that feeds a parallel combination of a generalized memory polynomial function and a memoryless polynomial function applied to the input signal's magnitude and phase, respectively. The present model is experimentally validated using a gallium nitride-based envelope tracking power amplifier driven by multi-carrier test signals.

### BACKGROUND OF THE INVENTION

1. Field of the Invention

The present invention relates to radio frequency (RF) power amplifiers, and particularly to a single-input single-output two-box polar behavioral model for envelope tracking power amplifiers using a complex magnitude and phase splitter that feeds a parallel combination of a generalized memory polynomial function and a memoryless polynomial function applied to the input signal's magnitude and phase, respectively.

2. Description of the Related Art

Radio frequency power amplifiers are critical circuits in wireless communication infrastructure. Their design often aims at reaching an acceptable trade-off between linearity and power efficiency. Indeed, the power amplifier (PA) is the major source of nonlinearity in wireless transmitters, and its power consumption is a predominant component that impacts the overall efficiency of the transmitter. On the one hand, linearity is essential in order to comply with spectrum emission regulations at the transmitter side and avoid loss of information at the receiver side. On the other hand, efficiency is essential in order to reduce the capital and operating expenses of base stations. It is also a major concern due to the increasingly alarming carbon footprint of wireless communication infrastructure. In the quest for linear and efficient power amplification systems, RF designers have investigated a wide range of power amplification architectures, including the Doherty architecture, linear amplification using nonlinear components (LINC), as well as the envelope tracking (ET) technique

For highly nonlinear circuits with strong memory effects, the generalized memory polynomial (GMP), is perceived as a reference model that achieves acceptable performance with reasonable complexity. This model was successfully applied for various power amplifier architectures, including single-ended class AB, as well as Doherty power amplifiers. However, the performance of the GMP model is found to deteriorate when efficiency-optimized shaping functions are used in the envelope path of envelope-tracking power amplifiers.

Thus, a single-input single-output two-box polar behavioral model for envelope tracking power amplifiers solving the aforementioned problems is desired.

### SUMMARY OF THE INVENTION

The single-input single-output two-box polar behavioral model for envelope tracking power amplifiers estimates magnitude and phase of the output signal in separate paths. More specifically, the model is a two-box polar behavioral model using a complex magnitude and phase splitter that feeds a parallel combination of a generalized memory polynomial function and a memoryless polynomial function applied to the input signal's magnitude and phase, respectively. The model is experimentally validated using a gallium nitride-based envelope tracking power amplifier driven by multi-carrier test signals.

These and other features of the present invention will become readily apparent upon further review of the following specification and drawings.

### BRIEF DESCRIPTION OF THE DRAWINGS

FIG. 1 is a block diagram of a single-input single-output two-box polar behavioral model for envelope tracking power amplifiers according to the present invention.

FIG. 2 is a block diagram showing a power amplifier in which the supply voltage is modulated by an envelope shaping function.

FIG. 3 is a plot illustrating NMSE (normalized mean square error) of the single-input single-output two-box polar behavioral model for envelope tracking power amplifiers according to the present invention as compared to a conventional generalized memory polynomial model.

Similar reference characters denote corresponding features consistently throughout the attached drawings.

### DETAILED DESCRIPTION OF THE PREFERRED EMBODIMENTS

At the outset, it should be understood by one of ordinary skill in the art that embodiments of the present method can comprise software or firmware code executing on a computer, a microcontroller, a microprocessor, or a DSP processor; state machines implemented in application specific or programmable logic; or numerous other forms without departing from the spirit and scope of the method described herein. The present method can be provided as a computer program, which includes a non-transitory machine-readable medium having stored thereon instructions that can be used to program a computer (or other electronic devices) to perform a process according to the method. The machine-readable medium can include, but is not limited to, floppy diskettes, optical disks, CD-ROMs, and magneto-optical disks, ROMs, RAMs, EPROMs, EEPROMs, magnetic or optical cards, flash memory, or other type of media or machine-readable medium suitable for storing electronic instructions.

The single-input single-output two-box polar behavioral model for envelope tracking power amplifiers estimates the magnitude and phase of the output signal in separate paths. More specifically, the model is a two-box polar behavioral model using a complex magnitude and phase splitter that feeds a parallel combination of a generalized memory polynomial function and a memoryless polynomial function applied to the input signal's magnitude and phase, respectively. The proposed model is experimentally validated using a gallium nitride-based envelope tracking power amplifier driven by multi-carrier test signals.

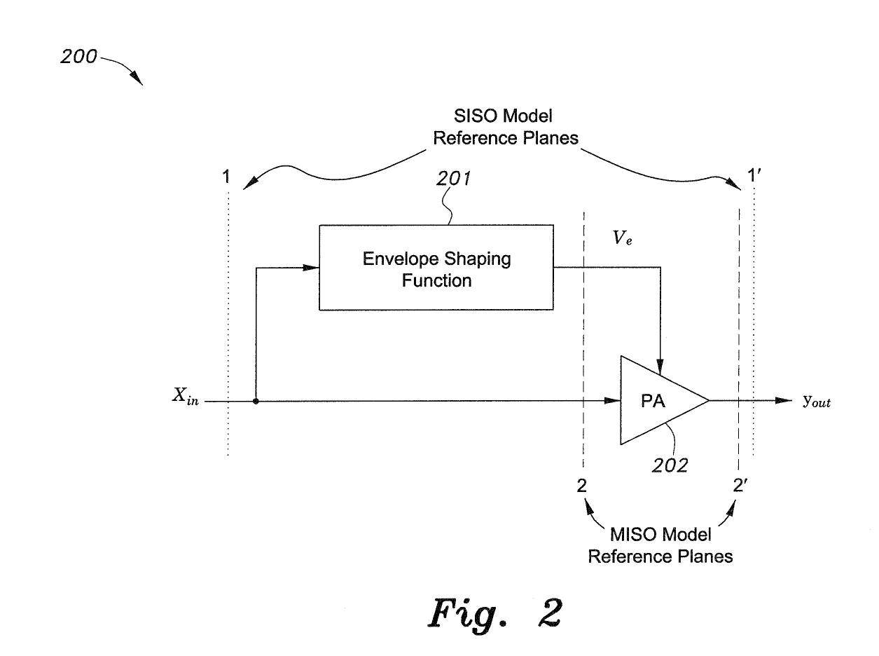

As shown in FIG. 2, the envelope tracking power amplifier 200 provides an envelope shaping function 201 that has a signal Xᵢₙ as its input and responsively provides an envelope shaping voltage Vₑ, which is applied to modulate the supply voltage of power amplifier 202. The input signal Xᵢₙ is also applied directly to the power amplifier 202 to produce the modulated output yₒᵤₜ of the power amplifier. This circuit can be considered as a single-input single-output (SISO) system if observed at reference planes 1 and 1′, or a multi-input single-output (MISO) system when characterized at reference planes 2 and 2′. The adoption of a two-input single-output behavioral model can offer superior modeling accuracy. However, it significantly increases the complexity of the model and makes the extraction of the corresponding digital predistortion function more complicated. For these reasons, single-input single-output models are adopted by the present model, as they offer a viable alternative for the modeling of envelope tracking power amplifiers.

The generalized memory polynomial (GMP) relates the baseband complex waveforms at the input and the output of the device under test (xᵢₙ and yₒᵤₜ, respectively) according to:

$${y}_{out} ( n ) = {\sum }_{m = 0}^{{M}_{1}} {\sum }_{k = 1}^{{K}_{1}} {a}_{mk} \cdot {x}_{in} ( n - m ) \cdot \vert {x}_{in} ( n - m ) {\vert}^{k - 1} + {\sum }_{m = 0}^{{M}_{2}} {\sum }_{k = 2}^{{K}_{2}} {\sum }_{p = 1}^{{P}_{2}} {b}_{mkp} \cdot {x}_{in} ( n - m ) \cdot \vert {x}_{in} ( n - m - p ) {\vert}^{k - 1} + {\sum }_{m = 0}^{{M}_{3}} {\sum }_{k = 2}^{{K}_{2}} {\sum }_{p = 1}^{{P}_{3}} {c}_{mkp} \cdot {x}_{in} ( n - m ) \cdot \vert {x}_{in} ( n - m + p ) {\vert}^{k - 1} \qquad ( 1 )$$

where aₘₖ, bₘₖₚ, and cₘₖₚ are the model's coefficients for the time-aligned, lagging, and leading memory polynomial branches, M₁ and K₁ are the memory depth and the nonlinearity order of the time-aligned memory polynomial branch, and M₂, K₂, and P₂ are the memory depth, the nonlinearity order, and the maximum deviation of the lagging cross-terms memory polynomial branch. Similarly, M₃, K₃, and P₃ are the memory depth, the nonlinearity order and the maximum deviation of the leading cross-terms memory polynomial branch.

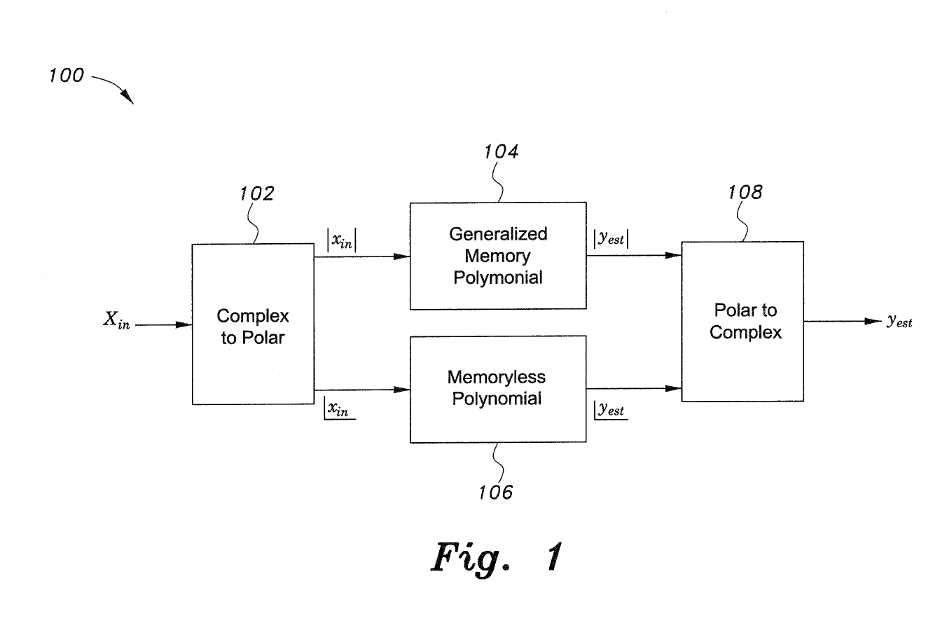

As it appears from Equation (1), the coefficients of the conventional generalized memory polynomial model are complex, and the model is applied on the complex input waveform samples. By contrast, in the present model, the magnitude and phase of the output signal are estimated in two separate paths. A generalized memory polynomial is applied for the prediction of the DUT's baseband output waveform's magnitude, whereas a memoryless polynomial function is used to predict the phase of the DUT's baseband output waveform. Both functions have real coefficients, since they are processing real variables (namely, the baseband signal's magnitude and its phase). As shown in FIG. 1, the block diagram of the present single-input single-output two-box polar behavioral model 100 includes a complex splitter 102 that decomposes the complex input signal Xᵢₙ into separate phase (<xᵢₙ) and magnitude (|xᵢₙ|) polar components. An electrical circuit connection of the complex splitter 102 to a generalized memory polynomial (GMP) function block 104 allows the magnitude of the input signal (|xᵢₙ|) to be applied to a look-up table (LUT), digital signal processor-based circuit, FPGA-based circuit, or other electronic implementation of the generalized memory polynomial known in the art. The GMP 104 responds by generating at its output, using a generalized memory polynomial function, an estimate (|yₑₛₜ|) of the magnitude of the DUT's baseband output signal. An electrical circuit connection of the complex splitter 102 to a memoryless polynomial (MP) function block 106 (implemented by a look-up table (LUT), digital signal processor-based circuit, FPGA-based circuit, or other electronic implementation of the memoryless polynomial known in the art) allows the phase of the DUT's input signal (<xᵢₙ) to be concurrently applied at the MP 106 input, the MP 106 responsively generating an estimated phase, (<yₑₛₜ), of the DUT's output signal. Finally, an electrical circuit connecting the GMP 104 to input circuitry of an amplitude phase combiner 108, and an electrical circuit connecting the MP 106 to the input circuitry of the amplitude phase combiner 108, allows the amplitude phase combiner 108 to combine the estimated magnitude |yₑₛₜ| and the estimated phase <yₑₛₜ of the DUT's baseband output waveform to produce at its output the complex baseband output waveform yₑₛₜ of the DUT.

Based on the above, the magnitude of the estimated output signal (|yₑₛₜ|) is expressed as a function of the magnitude of the input signal (|xᵢₙ|) according to:

$$\vert {y}_{est} ( n ) \vert = {\sum }_{m = 0}^{{M}_{1}} {\sum }_{k = 1}^{{K}_{1}} {a}_{mk} \cdot \vert {x}_{in} ( n - m ) {\vert}^{k} + {\sum }_{m = 0}^{{M}_{2}} {\sum }_{k = 2}^{{K}_{2}} {\sum }_{p = 1}^{{P}_{2}} {b}_{mkp} \cdot \vert {x}_{in} ( n - m ) \vert \cdot \vert {x}_{in} ( n - m - p ) {\vert}^{k - 1} + {\sum }_{m = 0}^{{M}_{3}} {\sum }_{k = 2}^{{K}_{2}} {\sum }_{p = 1}^{{P}_{3}} {c}_{mkp} \cdot \vert {x}_{in} ( n - m ) \vert \cdot \vert {x}_{in} ( n - m + p ) {\vert}^{k - 1} \qquad ( 2 )$$

where the model parameters M₁, K₁, M₂, K₂, P₂, M₃, K₃, and P₃ are similar to those defined for Equation (1). The model's coefficients for the time-aligned, lagging, and leading memory polynomial branches (aₘₖ, bₘₖₚ, and cₘₖₚ) are real-valued.

The memoryless polynomial function that relates the phases of the model's input and output signals is given by:

$$∠ {y}_{est} ( n ) = {\sum }_{k = 1}^{K} {d}_{k} \cdot ∠ {x}_{in} ( n ) \vert ∠ {x}_{in} ( n - m ) {\vert}^{k - 1} \qquad ( 3 )$$

where K and dₖ represent the model's nonlinearity order and its coefficients, respectively.

The envelope tracking power amplifier used in this work is built using a 10 W Gallium Nitride (GaN) transistor and operates around a carrier frequency of 2.425 GHz. The DUT was driven by a multi-carrier LTE signal having a total bandwidth of 20 MHz. The envelope tracking path of the DUT was built using a commercial envelope modulator. The shaping function used during the characterization of the DUT is the Nujira n6 shaping function. In this function, the variable DC supply voltage applied at the transistor's drain terminal (Vₑ) is derived from the baseband input signal waveform (xᵢₙ) through:

Vₑ(n)[Vₘᵢₙ⁶+Vₓ_{ᵢₙ}⁶(n)]^{1/6}, (4)

where Vₓ_{ᵢₙ}(n) is the instantaneous envelope voltage, and Vₘᵢₙ is the minimum voltage set by the commercial envelope modulator used.

The DUT's input signal was generated from the digital baseband waveform using an arbitrary waveform generator, and its output was acquired using a vector signal analyzer. The measured baseband input and output waveforms of the DUT were first time aligned, and then used to model the DUT's nonlinear behavior. For each set of measurements, the GMP and the present SISO two-box polar model were identified for various setting of their parameters. Indeed, in order to compare the performance of these models, the normalized mean squared error (NMSE) was calculated for a wide range of model parameters (nonlinearity order, memory depth, leading and lagging cross-terms orders, etc.). The normalized mean squared error is a commonly used metric for the performance assessment of power amplifiers' behavioral models and is given by:

$${NMSE}_{db} = 10 {log}_{10} ( \frac{1}{N} \frac{{Σ}_{n = 1}^{N} \vert {y}_{out} ( n ) - {y}_{est} ( n ) {\vert}^{2}}{{Σ}_{n = 1}^{N} \vert {y}_{out} ( n ) {\vert}^{2}} ) \qquad ( 5 )$$

where yₒᵤₜ and yₑₛₜ are the measured and estimated output waveforms of the DUT, respectively, and N is the number of samples in each of these baseband waveforms.

As the model parameters were varied, the NMSE between the estimated and measured DUT output signals was calculated for each set of model parameters. Since the conventional GMP model has complex coefficients, each of its complex coefficients is equivalent to two real-valued coefficients. In the present example, the GMP model refers to the single box model described by Equation (1).

A large number of model sizes was obtained by sweeping concurrently the eight parameters (nonlinearity order and memory depth of each of the three branches, in addition to the leading and lagging cross-terms orders) of the generalized memory polynomial model. Thus, a given model size, or equivalently, a total number of coefficients, was obtained by more than one combination of model parameters, leading to different NMSE performance.

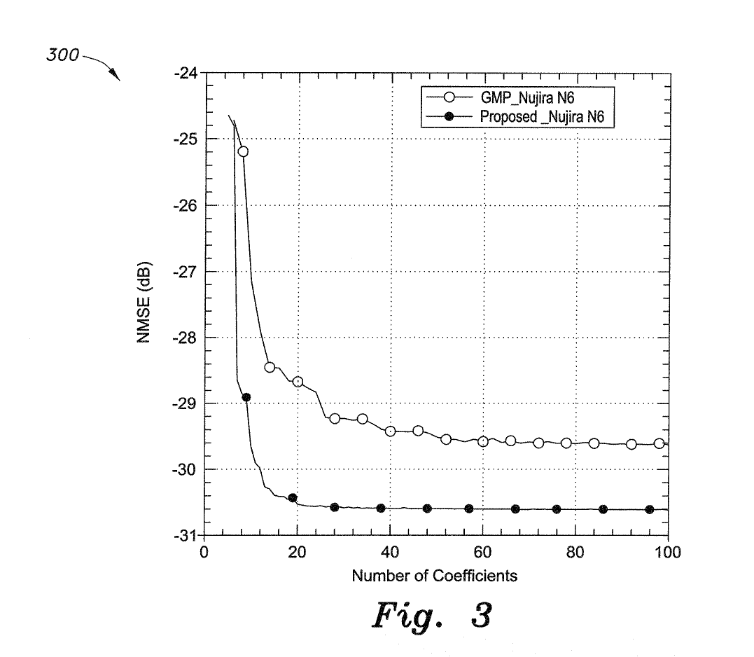

To assess the proposed model's performances, a test similar to that performed for the GMP model was carried out. During this test, the model parameters were swept, and the NMSE was calculated for each combination. The NMSE performance as a function of the total number of coefficients (including both boxes of the SISO two-box polar model) is reported in plot 300 of FIG. 3. Similar to the case of the GMP model, the model accuracy was evaluated for each total number of coefficients, but only the best NMSE is shown in FIG. 3.

As illustrated in the results of FIG. 3, one can clearly note that the present model outperforms the GMP model. In fact, for the same number of coefficients, the present model leads to 1 dB enhancement in the NMSE. Moreover, with only 20 coefficients, the present model achieves an NMSE of better than −30 dB. Such NMSE cannot be obtained with the GMP model, even if its size is increased up to 100 real-valued coefficients.

It is to be understood that the present invention is not limited to the embodiments described above, but encompasses any and all embodiments within the scope of the following claims.

We claim:

1. A single-input single-output two-box polar behavioral model for envelope tracking power amplifiers, comprising:
a complex splitter circuit for receiving a complex baseband input signal xᵢₙ and converting the input signal into corresponding separate phase (<xᵢₙ) and magnitude (|xᵢₙ|) output signals;
a memoryless polynomial (MP) circuit having an input connected to the phase output signal (<xᵢₙ) of the complex splitter, the MP circuit for generating an estimated phase output <yₑₛₜ signal corresponding to the (<xᵢₙ) input signal shaped by a memoryless polynomial function;
a generalized memory polynomial (GMP) circuit having an input connected to the magnitude output signal (|xᵢₙ|) of the complex splitter, the GMP circuit for generating an estimated magnitude output |yₑₛₜ| signal corresponding to the (|xᵢₙ|) input signal shaped by a generalized memory polynomial function; and
an amplitude phase combiner circuit having a first input receiving the estimated phase output <yₑₛₜ signal from the MP circuit and a second input for receiving the estimated magnitude output |yₑₛₜ| signal from the GMP circuit, the amplitude phase combiner circuit for generating an estimated complex output signal, yₑₛₜ, corresponding to the estimated phase output <yₑₛₜ signal and the estimated magnitude output |yₑₛₜ| signal.

2. The single-input single-output two-box polar behavioral model for envelope tracking power amplifiers according to claim 1, wherein the estimated magnitude output, |yₒᵤₜ|, is characterized by:
$$\vert {y}_{est} ( n ) \vert = {\sum }_{m = 0}^{{M}_{1}} {\sum }_{k = 1}^{{K}_{1}} {a}_{mk} \cdot \vert {x}_{in} ( n - m ) {\vert}^{k} + {\sum }_{m = 0}^{{M}_{2}} {\sum }_{k = 2}^{{K}_{2}} {\sum }_{p = 1}^{{P}_{2}} {b}_{mkp} \cdot \vert {x}_{in} ( n - m ) \vert \cdot \vert {x}_{in} ( n - m - p ) {\vert}^{k - 1} + {\sum }_{m = 0}^{{M}_{3}} {\sum }_{k = 2}^{{K}_{2}} {\sum }_{p = 1}^{{P}_{3}} {c}_{mkp} \cdot \vert {x}_{in} ( n - m ) \vert \cdot \vert {x}_{in} ( n - m + p ) {\vert}^{k - 1}$$
where the model parameters M₁ and K₁ are the memory depth and the nonlinearity order of the time-aligned memory polynomial branch; M₂, K₂, and P₂ are the memory depth, the nonlinearity order and maximum deviation of the lagging cross-terms memory polynomial branch; M₃, K₃, and P₃ are the memory depth, the nonlinearity order and maximum deviation of the leading cross-terms memory polynomial branch; and the model's coefficients for the time-aligned, lagging, and leading memory polynomial branches (aₘₖ, bₘₖₚ, and cₘₖₚ) are real-valued.

3. The single-input single-output two-box polar behavioral model for envelope tracking power amplifiers according to claim 2, wherein the estimated phase output <yₑₛₜ is characterized by:
$$∠ {y}_{est} ( n ) = {\sum }_{k = 1}^{K} {d}_{k} \cdot ∠ {x}_{in} ( n ) \vert ∠ {x}_{in} ( n - m ) {\vert}^{k - 1} ,$$
where K and dₖ represent the model's nonlinearity order and its coefficients, respectively.

4. In an envelope tracking power amplifier (PA), a single-input single-output two-box polar behavioral model-based predistortion method, comprising the steps of:
splitting a complex baseband input signal Xᵢₙ into a separate magnitude signal component |xᵢₙ|, and a separate phase signal component <xᵢₙ;
estimating a magnitude output |yₑₛₜ| corresponding to the |xᵢₙ| signal component by shaping the magnitude signal component using a generalized memory polynomial function;
estimating a phase output <yₑₛₜ responsive to the <xᵢₙ signal component by shaping the phase signal component using a memoryless polynomial function;
combining the estimated magnitude and phase outputs, |yₑₛₜ| and <yₑₛₜ, into an estimated complex output signal, yₑₛₜ; and
using the estimated complex output signal, yₑₛₜ, to form a predistortion signal for envelope control of the envelope tracking power amplifier (PA).

5. The single-input single-output two-box polar behavioral model method according to claim 4, further comprising the step of calculating the estimated magnitude output |yₑₛₜ| based on a formula characterized by the relation:
$$\vert {y}_{est} ( n ) \vert = {\sum }_{m = 0}^{{M}_{1}} {\sum }_{k = 1}^{{K}_{1}} {a}_{mk} \cdot \vert {x}_{in} ( n - m ) {\vert}^{k} + {\sum }_{m = 0}^{{M}_{2}} {\sum }_{k = 2}^{{K}_{2}} {\sum }_{p = 1}^{{P}_{2}} {b}_{mkp} \cdot \vert {x}_{in} ( n - m ) \vert \cdot \vert {x}_{in} ( n - m - p ) {\vert}^{k - 1} + {\sum }_{m = 0}^{{M}_{3}} {\sum }_{k = 2}^{{K}_{2}} {\sum }_{p = 1}^{{P}_{3}} {c}_{mkp} \cdot \vert {x}_{in} ( n - m ) \vert \cdot \vert {x}_{in} ( n - m + p ) {\vert}^{k - 1}$$
where the model parameters M₁ and K₁ are the memory depth and the nonlinearity order of the time-aligned memory polynomial branch; M₂, K₂, and P₂ are the memory depth, the nonlinearity order and maximum deviation of the lagging cross-terms memory polynomial branch; M₃, K₃, and P₃ are the memory depth, the nonlinearity order and maximum deviation of the leading cross-terms memory polynomial branch; and the model's coefficients for the time-aligned, lagging, and leading memory polynomial branches (aₘₖ, bₘₖₚ, and cₘₖₚ) are real-valued.

6. The single-input single-output two-box polar behavioral model method according to claim 5, further comprising the step of calculating the estimated phase output, <yₑₛₜ based on a formula characterized by the relation:
<yₑₛₜ(n)=Σₖ₌₁^{K}dₖ·<xᵢₙ(n)|<xᵢₙ(n−m)|^{k-1},
where K and dₖ represent the model's nonlinearity order and its coefficients, respectively.
